(19) United States
(12) Patent Application Publication
(10) Pub. No.: US 2026/0143791 A1
(43) Pub. Date: May 21, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Jun SAITO, Nisshin-shi (JP)

(21) Appl. No.: 19/349,194

(22) Filed: Oct. 3, 2025

(30) Foreign Application Priority Data
Nov. 19, 2024 (JP) 2024-201790

(51) Int. Cl. H10D 84/80; H10D 8/00; H10D 30/66; H10D 62/10; H10D 62/60

(52) U.S. Cl. CPC H10D 84/811; H10D 8/411; H10D 30/665; H10D 30/668; H10D 62/107; H10D 62/60

(57) ABSTRACT

A semiconductor substrate includes: a first n-type layer disposed within the peripheral region and located in a range including a corner between an upper surface and a side surface of the semiconductor substrate; a second n-type layer disposed within the peripheral region and located below the first n-type layer to be in contact with a lower electrode; and an n-type drift layer distributed across the element region and the peripheral region to have an n-type impurity concentration lower than those of the first n-type layer and the second n-type layer. The n-type drift layer is disposed between the first n-type layer and the second n-type layer and in contact with both of the first n-type layer and the second n-type layer. An anode of a diode is electrically connected to an anode electrode, and a cathode of the diode is electrically connected to the first n-type layer.

### CROSS REFERENCE TO RELATED APPLICATION

This application is based on Japanese Patent Application No. 2024-201790 filed on Nov. 19, 2024, the disclosure of which is incorporated herein by reference.

### TECHNICAL FIELD

The present disclosure relates to a semiconductor device.

### BACKGROUND

A protection circuit protects a switching element from a short circuit. The protection circuit includes a gate drive circuit and a diode for desaturation.

### SUMMARY

According to an aspect of the present disclosure, a semiconductor device includes: a semiconductor substrate having an element region and a peripheral region arranged around the element region; an upper electrode covering an upper surface of the semiconductor substrate within the element region; and a lower electrode covering a lower surface of the semiconductor substrate in an area over the element region and the peripheral region. The semiconductor device has: an insulating film covering the upper surface of the semiconductor substrate within the peripheral region; a semiconductor layer disposed on the insulating film and having a diode provided therein; and an anode electrode provided on the semiconductor substrate. A switching element capable of passing a current between the upper electrode and the lower electrode is provided in the element region. The semiconductor substrate has a first n-type layer disposed within the peripheral region and located in a range including a corner between the upper surface and a side surface of the semiconductor substrate. The semiconductor substrate has a second n-type layer disposed within the peripheral region and located below the first n-type layer and in contact with the lower electrode. The semiconductor substrate has a n-type drift layer distributed across the element region and the peripheral region to have a lower n-type impurity concentration than the first n-type layer and the second n-type layer. The drift layer is disposed between the first n-type layer and the second n-type layer to be in contact with both the first n-type layer and the second n-type layer. An anode of the diode may be electrically connected to the anode electrode, and a cathode of the diode may be electrically connected to the first n-type layer.

### BRIEF DESCRIPTION OF DRAWINGS

FIG. 1 is a circuit diagram in which a semiconductor device is provided.

FIG. 2 is a plan view illustrating a semiconductor device according to a first embodiment.

FIG. 3 is a cross-sectional view taken along line III-III of FIG. 2, as a schematic diagram of the semiconductor device of the first embodiment.

FIG. 4A is an explanatory diagram illustrating a diode in the first embodiment.

FIG. 4B is an enlarged view of an area IVB of FIG. 4A.

FIG. 5 is an explanatory diagram illustrating another structure of a diode in the first embodiment.

FIG. 6 is a schematic diagram of a semiconductor device according to a second embodiment.

FIG. 7 is a schematic diagram of a semiconductor device according to a third embodiment.

FIG. 8 is a schematic diagram of a semiconductor device according to a modified example.

### DETAILED DESCRIPTION

A protection circuit protects a switching element from a short circuit. The protection function is sometimes called DESAT (Desaturation). The protection circuit includes a gate drive circuit and a diode for DESAT. The anode of the diode is connected to the gate drive circuit, and the cathode of the diode is connected to the high potential terminal (such as collector or drain) of the switching element. The diode prevents a high voltage from being input from the high potential terminal to the gate drive circuit. The gate drive circuit detects the potential of the high potential terminal via the diode. The gate drive circuit determines whether or not an overcurrent is flowing through the switching element from the potential of the high potential terminal. The gate drive circuit turns off the switching element when it is determined that an overcurrent is flowing through the switching element.

When the diode for DESAT is externally attached to the switching element, the protection circuit becomes large. This specification provides techniques for downsizing the protection circuit.

According to an aspect of the present disclosure, a semiconductor device includes: a semiconductor substrate having an element region and a peripheral region arranged around the element region; an upper electrode covering an upper surface of the semiconductor substrate within the element region; and a lower electrode covering a lower surface of the semiconductor substrate in an area over the element region and the peripheral region. The semiconductor device has: an insulating film covering the upper surface of the semiconductor substrate within the peripheral region; a semiconductor layer disposed on the insulating film and having a diode provided therein; and an anode electrode provided on the semiconductor substrate. A switching element capable of passing a current between the upper electrode and the lower electrode is provided in the element region. The semiconductor substrate has: a first n-type layer disposed within the peripheral region and located in a range including a corner between the upper surface and a side surface of the semiconductor substrate. The semiconductor substrate has a second n-type layer disposed within the peripheral region and located below the first n-type layer to be in contact with the lower electrode. The semiconductor substrate has an n-type drift layer distributed across the element region and the peripheral region to have a lower n-type impurity concentration than the first n-type layer and the second n-type layer. The drift layer is disposed between the first n-type layer and the second n-type layer to be in contact with both the first n-type layer and the second n-type layer. An anode of the diode is electrically connected to the anode electrode, and a cathode of the diode is electrically connected to the first n-type layer.

In the semiconductor device, the diode provided in the semiconductor layer can be used as a diode for DESAT. Since the semiconductor layer including the diode is integrated with the semiconductor substrate in which the switching element is provided, the protection circuit can be made compact.

A semiconductor device disclosed in this specification may further include a semi-insulating film disposed between the insulating film and the semiconductor layer. The semi-insulating film may be electrically connected to the upper electrode and the first n-type layer.

According to this configuration, the equipotential lines are distributed in a dispersed manner within the semi-insulating film. This makes it possible to suppress mutual influence of electric fields between the semiconductor layer above the semi-insulating film and the semiconductor substrate below the semi-insulating film.

In a semiconductor device disclosed in this specification, the diode may have a first anode layer of p-type, a first cathode layer of n-type spaced apart from the first anode layer in a lateral direction, and a stacked portion disposed between the first anode layer and the first cathode layer. The stacked portion may have a structure in which a p-type second anode layer and an n-type second cathode layer are stacked with each other. The second anode layer may have a lower p-type impurity concentration than the first anode layer, and the second cathode layer may have a lower n-type impurity concentration than the first cathode layer. The second anode layer may be in contact with the first anode layer at a side surface of the stacked portion, and the second cathode layer may be in contact with the first cathode layer at a side surface of the stacked portion.

With this configuration, the stacked portion is easily depleted. In the depleted stacked portion, the equipotential lines tend to disperse, so that electric field concentration in the semiconductor layer can be suppressed.

The semiconductor device may further include a p-type voltage-resistant layer disposed within the peripheral region and located in an area including the upper surface of the semiconductor substrate. The p-type voltage-resistant layer is provided between the element region and the first n-type layer. The p-type voltage-resistant layer may be spaced apart from the element region and from the first n-type layer. The drift layer may be present between the p-type voltage-resistant layer and the element region, and between the p-type voltage-resistant layer and the first n-type layer.

In the semiconductor device, for example, the semiconductor layer may be provided within a range overlapping with the p-type voltage-resistant layer when viewed in a thickness direction of the semiconductor substrate.

According to this configuration, it is possible to suppress mutual influence of electric fields between the semiconductor layer above the p-type voltage-resistant layer and the semiconductor substrate below the p-type voltage-resistant layer.

The semiconductor device may include, for example, plural p-type voltage-resistant layers. The semiconductor layer may have a first semiconductor layer arranged on an upper portion of a first p-type voltage-resistant layer of the plural p-type voltage-resistant layers, and a second semiconductor layer arranged on an upper portion of a second p-type voltage-resistant layer of the plural p-type voltage-resistant layers. A first diode provided in the first semiconductor layer and a second diode provided in the second semiconductor layer may be connected in series between the anode electrode and the first n-type layer with an anode facing the anode electrode.

This configuration improves the voltage resistance of the diode.

In the semiconductor device, for example, the p-type voltage-resistant layer may have a ring shape surrounding the element region. The diode may have a p-type anode layer provided in the semiconductor layer, and an n-type cathode layer provided in the semiconductor layer. The anode layer and the cathode layer may be arranged along a longitudinal direction of the p-type voltage-resistant layer.

This configuration can improve the voltage resistance of the diode.

In the semiconductor device, for example, the p-type voltage-resistant layer may have a ring shape surrounding the element region. The diode may have a p-type anode layer provided in the semiconductor layer, and an n-type cathode layer provided in the semiconductor layer. Furthermore, a pn junction at a boundary between the anode layer and the cathode layer may have a ring shape extending along the p-type voltage-resistant layer.

The lateral direction in the description of the semiconductor device means a direction parallel to the upper surface of the semiconductor device.

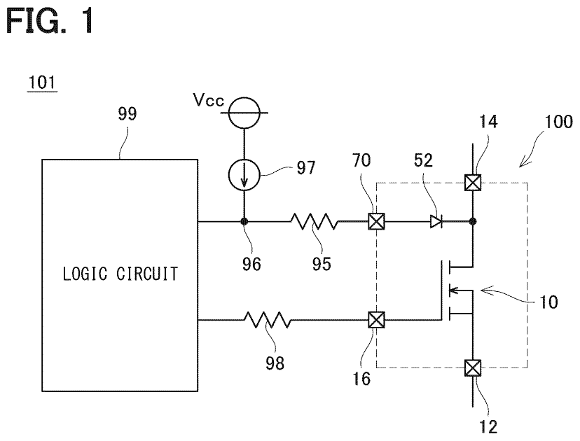

FIG. 1 shows a circuit 101 including a semiconductor device 100 according to an embodiment. The semiconductor device 100 includes a metal-oxide-semiconductor field effect transistor (MOSFET) 10. The circuit 101 controls the operation of the MOSFET 10. The circuit 101 functions as a protection circuit that turns off the MOSFET 10 when an overcurrent flows through the MOSFET 10. The MOSFET 10 has a source electrode 12, a drain electrode 14, and a gate electrode 16. The drain electrode 14 is connected to a high potential wiring. The source electrode 12 is connected to a low potential wiring. The gate electrode 16 is electrically connected to an output terminal of a logic circuit 99 via a resistor 98. The logic circuit 99 controls the potential of the gate electrode 16. The semiconductor device 100 includes a diode 52 and an anode electrode 70. The cathode of the diode 52 is electrically connected to the drain electrode 14. The anode of the diode 52 is electrically connected to the anode electrode 70. The anode electrode 70 is connected to one end of a resistor 95. The other end of the resistor 95 is connected to a potential detection terminal of the logic circuit 99 via a wiring 96. The circuit 101 includes a constant current source 97. The power supply terminal of the constant current source 97 is connected to the potential Vcc. The output terminal of the constant current source 97 is connected to the wiring 96.

Next, the operation of the circuit 101 will be described. The logic circuit 99 switches the MOSFET 10 by changing the potential of the gate electrode 16. When the logic circuit 99 controls the potential of the gate electrode 16 to a potential equal to or higher than the gate threshold (hereinafter referred to as gate-on potential), the MOSFET 10 is turned on. When the MOSFET 10 is on, a current flows from the drain electrode 14 to the source electrode 12 through the MOSFET 10, and the potentials of the drain electrode 14 and the source electrode 12 become substantially equal. In this case, the diode 52 is turned on, and a current flows from the constant current source 97 through the resistor 95, the anode electrode 70, the diode 52, and the MOSFET 10 to the source electrode 12. Therefore, the potential of the wiring 96 becomes a low potential that is approximately equal to that of the source electrode 12. In this case, the logic circuit 99 detects the potential of the wiring 96 as being low.

When the logic circuit 99 controls the potential of the gate electrode 16 to a potential less than the gate threshold (hereinafter referred to as the gate-off potential), the MOSFET 10 is turned off. When the MOSFET 10 is off, the drain electrode 14 is at a high potential and the diode 52 is off. Then, the wiring 96 is charged by the current supplied from the constant current source 97, so that the potential of the wiring 96 rises to the potential Vcc. In this case, the logic circuit 99 detects the potential Vcc as the potential of the wiring 96.

When the MOSFET 10 is in an on-state, a load connected to the MOSFET 10 may be short-circuited, causing a saturation current to flow through the MOSFET 10. When a saturation current flows through the MOSFET 10, the potential of the drain electrode 14 becomes high even when the MOSFET 10 is in the on-state. Therefore, when a saturation current flows, the diode 52 is turned off and the potential of the wiring 96 becomes the potential Vcc. In this case, the logic circuit 99 detects the potential Vcc as the potential of the wiring 96. Therefore, the logic circuit 99 determines that a saturation current is flowing through the MOSFET 10 if the potential of the wiring 96 rises to the potential Vcc when the MOSFET 10 is on. When the logic circuit 99 determines that a saturation current is flowing, the MOSFET 10 is turned off. This protects the MOSFET 10 from overcurrent.

### First Embodiment

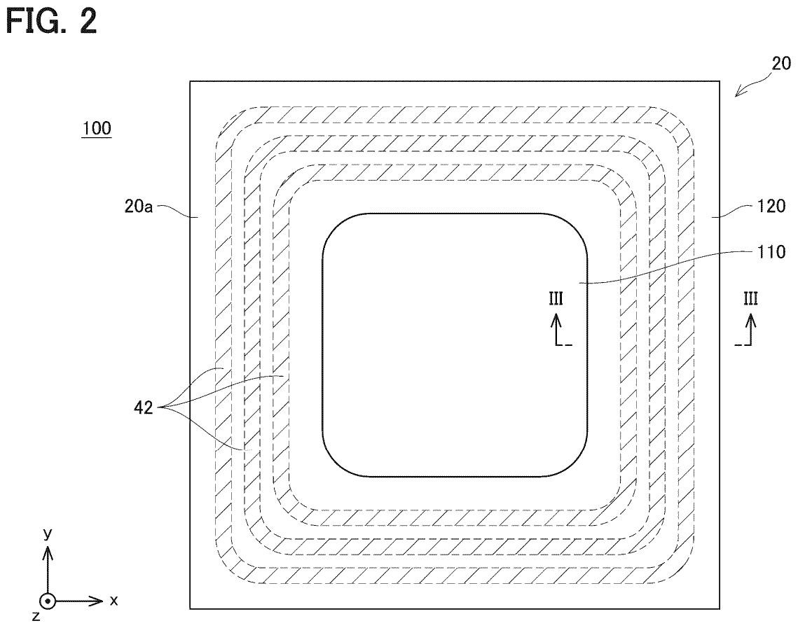

As illustrated in FIG. 2, the semiconductor device 100 according to a first embodiment includes a semiconductor substrate 20. A thickness direction of the semiconductor substrate 20 is referred to as z direction. A direction parallel to the upper surface 20a of the semiconductor substrate 20 is referred to as x direction. A direction parallel to the upper surface 20a of the semiconductor substrate 20 and perpendicular to the x direction is referred to as y direction. The semiconductor substrate 20 is a SiC substrate. The semiconductor substrate 20 may be composed of other semiconductor materials such as silicon or gallium nitride. The semiconductor substrate 20 includes an element region 110 and a peripheral region 120. When the semiconductor device 100 is viewed from the upper side, the element region 110 is disposed in the center of the semiconductor substrate 20. When the semiconductor device 100 is viewed from the upper side, the peripheral region 120 is disposed around the element region 110.

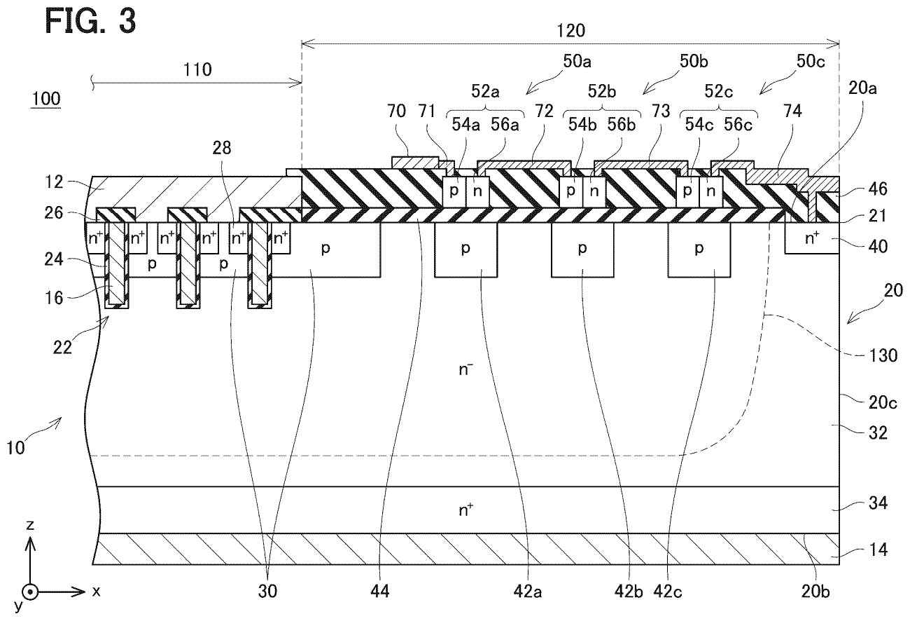

The semiconductor device 100 has the source electrode 12 and the drain electrode 14. As shown in FIG. 3, the source electrode 12 covers the upper surface 20a of the semiconductor substrate 20 in the element region 110. The drain electrode 14 covers the lower surface 20b of the semiconductor substrate 20 in an area over the element region 110 and the peripheral region 120. In other words, the drain electrode 14 covers the entire lower surface 20b of the semiconductor substrate 20.

The MOSFET 10 is provided in the element region 110. The MOSFET 10 allows a current to flow from the drain electrode 14 to the source electrode 12 along the thickness direction (z direction) of the semiconductor substrate 20.

Plural trenches 22 are provided in the upper surface 20a of the semiconductor substrate 20 in the element region 110. The semiconductor device 100 includes a gate insulating film 24, a gate electrode 16, and an interlayer insulating film 26. The gate insulating film 24 and the gate electrode 16 are disposed in the trench 22. The gate insulating film 24 covers an inner surface of the trench 22. The gate electrode 16 is provided inside the gate insulating film 24. The gate electrode 16 is insulated from the semiconductor substrate 20 by the gate insulating film 24. The interlayer insulating film 26 covers an upper surface of the gate electrode 16. The gate electrode 16 is insulated from the source electrode 12 by the interlayer insulating film 26.

The semiconductor substrate 20 has a source layer 28 and a body layer 30 in the element region 110. The source layer 28 is an n-type layer. The source layer 28 is disposed in a range including the upper surface 20a. The source layer 28 is in contact with the source electrode 12. The source layer 28 is in contact with the gate insulating film 24 on the side surface of the corresponding trench 22.

The body layer 30 is a p-type layer. The body layer 30 is disposed in a range including the upper surface 20a. The body layer 30 is in contact with the source electrode 12. The body layer 30 is distributed from the lateral side to the lower side of the source layer 28 and is in contact with the source layer 28. The body layer 30 is in contact with the gate insulating film 24 on the side surface of the trench 22 below the source layer 28.

The semiconductor substrate 20 has a drift layer 32 and a drain layer 34. The drift layer 32 is an n-type layer having an n-type impurity concentration lower than that of the source layers 28. The drift layer 32 is distributed across the element region 110 and the peripheral region 120. The drift layer 32 is in contact with the body layer 30 within the element region 110. The drift layer 32 is in contact with the gate insulating film 24 on the side surface of the trench 22 below the body layer 30 and on the bottom surface of the trench 22 in the element region 110. The drift layer 32 is disposed in a range including the upper surface 20a, within the peripheral region 120.

The drain layer 34 is an n-type layer having an n-type impurity concentration higher than that of the drift layer 32. The drain layer 34 is distributed across the element region 110 and the peripheral region 120. The drain layer 34 is in contact with the lower surface of the drift layer 32. The drain layer 34 is disposed in a range including the lower surface 20b of the semiconductor substrate 20. The drain layer 34 is in contact with the drain electrode 14 over the entire lower surface 20b.

The semiconductor substrate 20 has a peripheral n-type layer 40 and plural guard rings 42 in the peripheral region 120. The peripheral n-type layer 40 is an n-type layer having a higher n-type impurity concentration than the drift layer 32. The peripheral n-type layer 40 is disposed in a range including the corner 21 between the upper surface 20a and the side surface 20c of the semiconductor substrate 20. The side and bottom surfaces of the peripheral n-type layer 40 are in contact with the drift layer 32. The drain layer 34 is disposed below the peripheral n-type layer 40. That is, the drift layer 32 is disposed between the peripheral n-type layer 40 and the drain layer 34. The drift layer 32 separates the peripheral n-type layer 40 from the drain layer 34.

The guard rings 42 are p-type layers, and are disposed in an area including the upper surface 20a of the semiconductor substrate 20. The guard rings 42 are provided between the element region 110 and the peripheral n-type layer 40. The guard rings 42 are provided at intervals in a direction from the element region 110 toward the peripheral n-type layer 40 (i.e., the side surface 20c of the semiconductor substrate 20). The side and bottom surfaces of each guard ring 42 (i.e., the periphery of the guard ring 42) are in contact with the drift layer 32. The guard rings 42a to 42c are separated from one another by the drift layer 32. A gap is provided between the guard ring 42a that is closest to the element region 110 and the body layer 30. The guard ring 42a and the body layer 30 are separated by the drift layer 32. A gap is provided between the peripheral n-type layer 40 and the guard ring 42c that is closest to the peripheral n-type layer 40. The guard ring 42c and the peripheral n-type layer 40 are separated by the drift layer 32. When the semiconductor device 100 is viewed from the upper side, each of the guard rings 42 has a ring shape surrounding the element region 110.

The semiconductor device 100 has an insulating film 44 in the peripheral region 120. The insulating film 44 covers an area that includes the upper surface 20a of the semiconductor substrate 20, within the peripheral region 120. The insulating film 44 covers the body layer 30, the drift layer 32, and the guard ring 42 in the peripheral region 120. The insulating film 44 does not cover the peripheral n-type layer 40.

The semiconductor device 100 has plural semiconductor layers 50 in the peripheral region 120. Each of the semiconductor layers 50 is made of polycrystalline Si. The semiconductor layer 50 may be made of a material such as single crystal Si or SiC. The semiconductor layer 50 is disposed on the insulating film 44. The semiconductor layer 50 is insulated from the semiconductor substrate 20 by the insulating film 44. The semiconductor layer 50 is provided within an area overlapping the corresponding guard ring 42 when viewed in the z direction. That is, a semiconductor layer 50a is provided at a position overlapping with the guard ring 42a, a semiconductor layer 50b is provided at a position overlapping with the guard ring 42b, and a semiconductor layer 50c is provided at a position overlapping with the guard ring 42c. Each of the semiconductor layers 50 has a smaller width in the x direction than the corresponding guard ring 42. Each of the semiconductor layers 50 is disposed within the width of the corresponding guard ring 42 in the x direction.

Each of the semiconductor layers 50 is provided with a p-type anode layer 54 and an n-type cathode layer 56. The anode layer 54 and the cathode layer 56 form the diode 52. The anode layer 54 is disposed closer to the element region 110 in the x direction (hereinafter referred to as the inner periphery side). The cathode layer 56 is disposed closer to the side surface 20c of the semiconductor substrate 20 in the x direction (hereinafter referred to as the outer periphery side). The side surface of the anode layer 54 is in contact with the side surface of the cathode layer 56. In the following description, the diodes 52 provided in the semiconductor layers 50a, 50b, 50c are referred to as diodes 52a, 52b, 52c. The anode layers 54 of the diodes 52a, 52b, 52c are referred to as anode layers 54a, 54b, 54c, and the cathode layers 56 of the diodes 52a, 52b, 52c are referred to as 56a, 56b, 56c.

The semiconductor device 100 has the insulating film 46 in the peripheral region 120. The insulating film 46 is provided on the insulating film 44. The insulating film 46 covers the semiconductor layers 50a to 50c and the peripheral n-type layer 40.

The semiconductor device 100 has the anode electrode 70. The anode electrode 70 is provided on the insulating film 46. The anode electrode 70 is separated from the source electrode 12, the drain electrode 14, and the gate electrode 16.

The semiconductor device 100 has wiring layers 71, 72, 73, and 74 provided on the insulating film 46. The wiring layer 71 connects the anode electrode 70 and the anode layer 54a. The wiring layer 72 connects the cathode layer 56a and the anode layer 54b. The wiring layer 73 connects the cathode layer 56b and the anode layer 54c. The wiring layer 74 connects the cathode layer 56c and the peripheral n-type layer 40. Therefore, the diode 52a, 52b and the diode 52c are connected in series between the anode electrode 70 and the peripheral n-type layer 40 with the anode layer 54 facing the anode electrode 70.

When the MOSFET 10 is turned off, a depletion layer spreads from the body layer 30 to the drift layer 32. The depletion layer extends to the position indicated by a dashed line 130 in FIG. 3. As shown in FIG. 3, the drift layer 32 is not depleted below the peripheral n-type layer 40. Therefore, whether the MOSFET 10 is on or off, the peripheral n-type layer 40 is electrically connected to the drain electrode 14 by the drift layer 32 and drain layer 34 on the lower side. Therefore, the diodes 52a, 52b, 52c are connected in series between the anode electrode 70 and the drain electrode 14 with the anode layer 54 facing the anode electrode 70. In FIG. 1, the three diodes 52a, 52b, 52c are shown as the diode 52. As described above, the diode 52 is connected between the anode electrode 70 and the drain electrode 14 with the anode adjacent to the anode electrode 70. In this manner, by configuring the diode 52 with the three diodes 52a, 52b, 52c connected in series, the voltage resistance of the diode 52 is improved.

In the semiconductor device 100 of the first embodiment, the MOSFET 10 and the diode 52 are provided in a common semiconductor device 100. Therefore, the circuit can be made smaller than when a diode for DESAT is externally attached to the MOSFET.

As described above, when the MOSFET 10 is turned off, a depletion layer extends from the body layer 30 into the drift layer 32 to the position of the dashed line 130. Since the guard ring 42 promotes the extension of the depletion layer in the drift layer 32, the depletion layer extends beyond the outermost guard ring 42c. An electric field is generated in the depleted drift layer 32. Since the guard ring 42 has a high p-type impurity concentration, the guard ring 42a, 42b, 42c is not depleted. When the MOSFET 10 is turned off, a reverse voltage is applied to the diode 52, causing the semiconductor layer 50a, 50b, 50c to be depleted. As a result, an electric field is generated in the semiconductor layer 50a, 50b, 50c. Since the depleted semiconductor layer 50a, 50b, 50c is disposed above the non-depleted guard ring 42a, 42b, 42c, it is possible to suppress the electric field inside the semiconductor layers 50a, 50b, 50c and the electric field inside the drift layer 32 from influencing each other. This makes it possible to suppress electric field concentration in the drift layer 32. Furthermore, the operation of the diode 52a, 52b, 52c becomes stable.

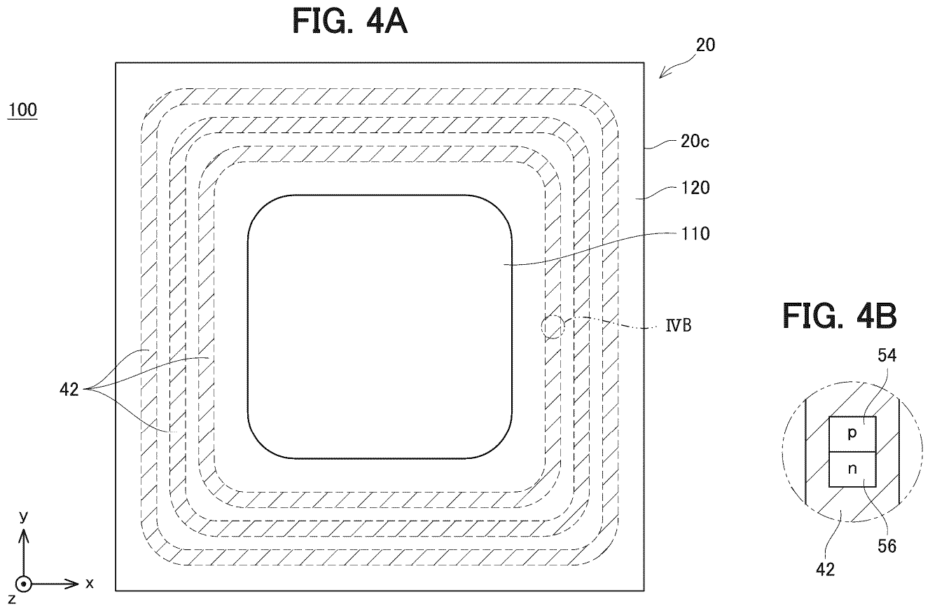

In the first embodiment, when the semiconductor device 100 is viewed from the upper side, the anode layer 54 and the cathode layer 56 are adjacent to each other in the width direction of the guard ring 42 (i.e., the direction from the element region 110 toward the side surface 20c). However, as shown in FIGS. 4A and 4B, when the semiconductor device 100 is viewed from the upper sid, the anode layer 54 and the cathode layer 56 may be adjacent to each other in the longitudinal direction of the guard ring 42 (i.e., the direction parallel to the side surface 20c). According to this configuration, the width of the anode layer 54 and the width of the cathode layer 56 can be increased in the direction perpendicular to the pn junction. Therefore, the voltage resistance of the diode 52 can be increased.

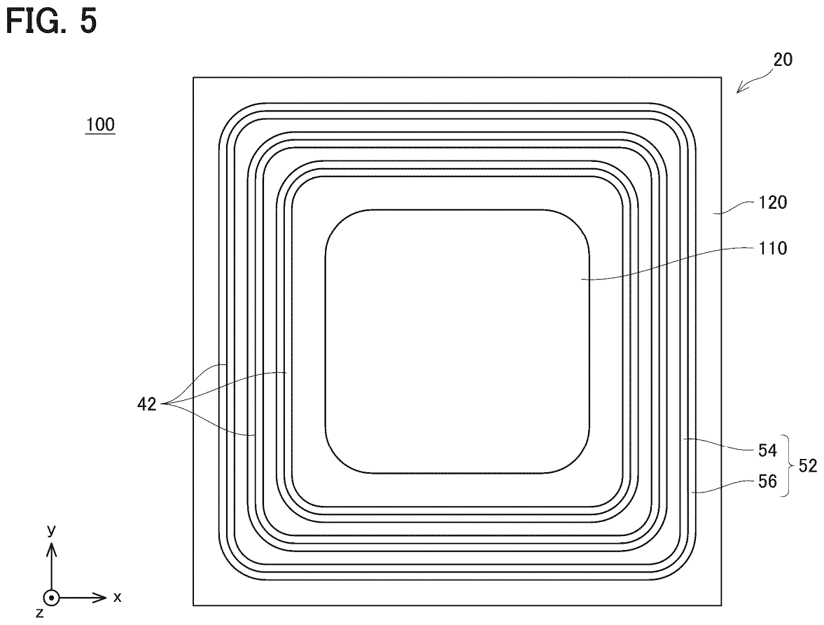

In the first embodiment, as shown in FIG. 5, each of the diodes 52 may have a ring shape surrounding the element region 110 when the semiconductor device 100 is viewed from the upper sid. That is, the pn junction at the boundary between the anode layer 54 and the cathode layer 56 may have a ring shape extending along the corresponding guard ring 42. According to this configuration, the characteristics of the diode 52 are stable.

### Second Embodiment

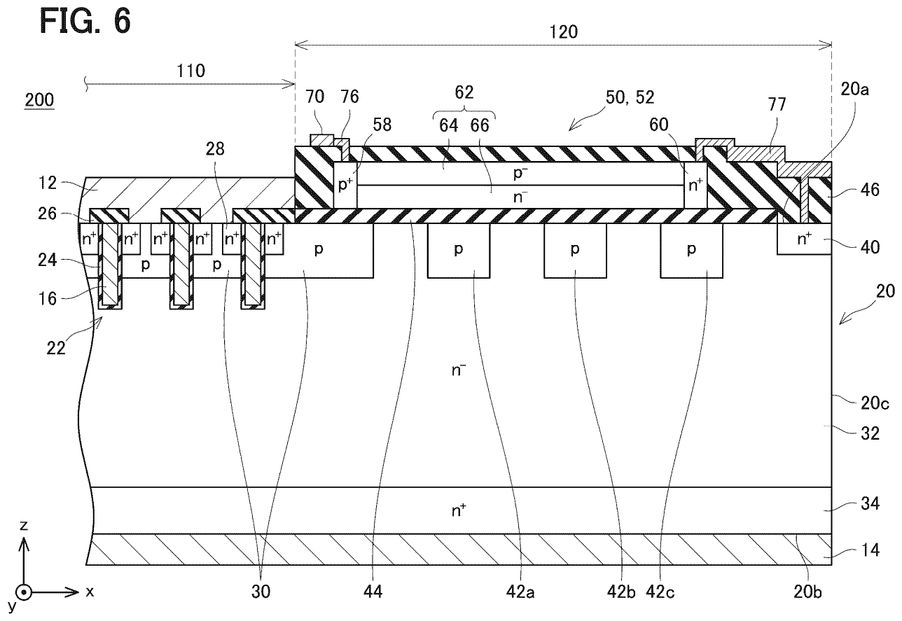

In a semiconductor device 200 according to a second embodiment, as shown in FIG. 6, the structure of the upper part of the insulating film 44 is different from that of the first embodiment. The other configurations of the semiconductor device 200 of the second embodiment are the same as those of the first embodiment. In FIG. 6, the same parts as those in FIG. 3 are denoted by the same reference numerals.

In the second embodiment, the semiconductor layer 50 is disposed on the insulating film 44 and is distributed to extend over the tops of the guard rings 42. The semiconductor layer 50 is covered with the insulating film 46. When viewed in the z direction, the semiconductor layer 50 extends from a position overlapping with the body layer 30 to a position overlapping with the guard ring 42c. The semiconductor layer 50 is provided with the diode 52. The diode 52 includes a first anode layer 58, a first cathode layer 60 and a stacked portion 62. The first anode layer 58 is a p-type layer. The first anode layer 58 is disposed at a position overlapping with the body layer 30 when viewed in the z direction.

The first cathode layer 60 is an n-type layer. The first cathode layer 60 is disposed at a position overlapping with the guard ring 42c when viewed in the z direction. The first cathode layer 60 is spaced apart from the first anode layer 58 in the x direction.

The stacked portion 62 is disposed between the first anode layer 58 and the first cathode layer 60. One side of the stacked portion 62 is in contact with the first anode layer 58, and the other side of the stacked portion 62 is in contact with the first cathode layer 60. The stacked portion 62 includes a second anode layer 64 and a second cathode layer 66.

The second cathode layer 66 is an n-type layer having a lower n-type impurity concentration than the first cathode layer 60. The second cathode layer 66 is in contact with the upper surface of the insulating film 44. The second cathode layer 66 extends from the first anode layer 58 to the first cathode layer 60 in the x direction. One side of the second cathode layer 66 is in contact with the first anode layer 58, and the other side of the second cathode layer 66 is in contact with the first cathode layer 60.

The second anode layer 64 is a p-type layer having a lower p-type impurity concentration than the first anode layer 58. The second anode layer 64 is in contact with the upper surface of the second cathode layer 66. The second anode layer 64 extends from the first anode layer 58 to the first cathode layer 60 in the x direction. One side of the second anode layer 64 is in contact with the first anode layer 58, and the other side of the second anode layer 64 is in contact with the first cathode layer 60.

The semiconductor device 200 has a wiring layer 76 and a wiring layer 77 provided on the insulating film 46. The wiring layer 76 connects the anode electrode 70 and the first anode layer 58. The wiring layer 77 connects the first cathode layer 60 and the peripheral n-type layer 40. The diode 52 is connected between the anode electrode 70 and the peripheral n-type layer 40 with the first anode layer 58 located adjacent to the anode electrode 70.

In the second embodiment, since the MOSFET and the diode for DESAT are provided in the common semiconductor device 200, the circuit can be made smaller.

As described above, the stacked portion 62 has a structure in which the second anode layer 64 and the second cathode layer 66 are stacked with each other. According to this structure, a depletion layer extends from the pn junction in the thickness direction of the second anode layer 64 and the second cathode layer 66. Since the second anode layer 64 and the second cathode layer 66 are thin, the second anode layer 64 and the second cathode layer 66 (i.e., the stacked portion 62) are entirely depleted. In the depleted stacked portion 62, the equipotential lines tend to disperse in the x direction. As a result, electric field concentration is unlikely to occur in the semiconductor layer 50. This makes it difficult for electric field concentration to occur in the drift layer 32.

### Third Embodiment

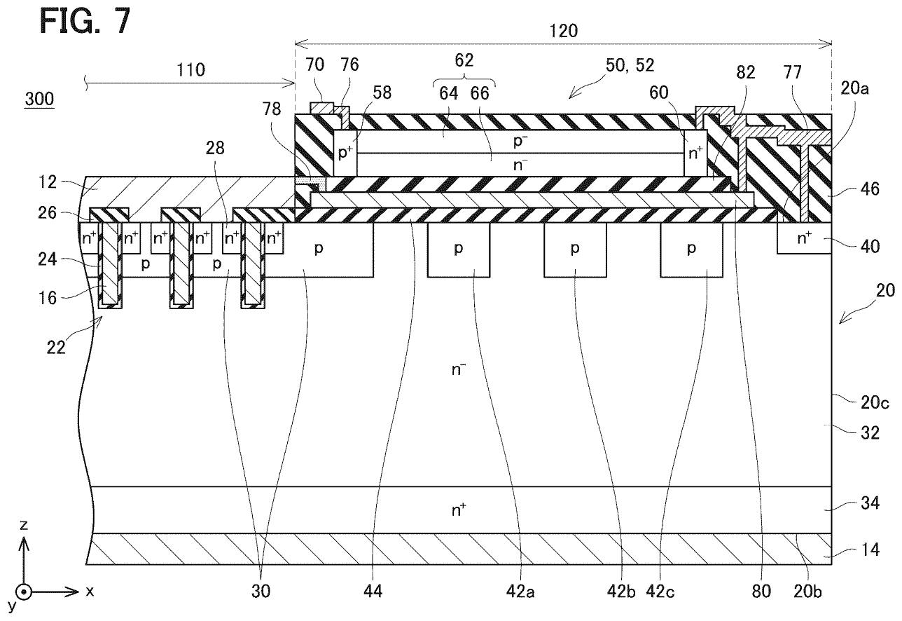

In a semiconductor device 300 according to a third embodiment, as shown in FIG. 7, the structure of the upper part of the insulating film 44 is different from that of the second embodiment. In other respects, the semiconductor device 300 of the third embodiment is the same as that of the second embodiment. The semiconductor device 300 has a semi-insulating film 80, an insulating film 82, a semiconductor layer 50, and an insulating film 46 above the insulating film 44.

The semi-insulating film 80 is disposed on the insulating film 44 and is distributed to extend across the upper portions of the guard rings 42. When viewed in the z direction, the semi-insulating film 80 extends from the position overlapping with the body layer 30 to the outside of the guard ring 42c. The semi-insulating film 80 may be made of, for example, semi-insulating silicon nitride. The semi-insulating film 80 may be made of other materials such as high-resistance polysilicon. The end of the semi-insulating film 80 closer to the element region 110 is connected to the source electrode 12 by a wiring layer 78. The outer peripheral end of the semi-insulating film 80 is connected to the peripheral n-type layer 40 by a wiring layer 77.

The insulating film 82 is disposed on the semi-insulating film 80.

The semiconductor layer 50 is disposed on the insulating film 82 and is distributed to extend over the tops of the guard rings 42. The semiconductor layer 50 is covered with the insulating film 46. The diode 52 is provided in the semiconductor layer 50. The structure of the diode 52 is the same as that in the second embodiment.

In the third embodiment, since the MOSFET and the diode for DESAT are provided in the common semiconductor device 300, the circuit can be made compact.

In the third embodiment, the stacked portion 62 is depleted, so that electric field concentration is unlikely to occur in the semiconductor layer 50. This makes it possible to suppress electric field concentration in the drift layer 32.

In the third embodiment, a minute current flows through the semi-insulating film 80 from the drain electrode 14 to the source electrode 12. As a result, the potential is dispersed in the semi-insulating film 80 in the direction from the element region 110 toward the side surface 20c. Therefore, it is possible to suppress mutual influence of electric fields between the semiconductor layer 50 located above the semi-insulating film 80 and the drift layer 32 located under the semi-insulating film 80. This makes it possible to suppress electric field concentration in the drift layer 32.

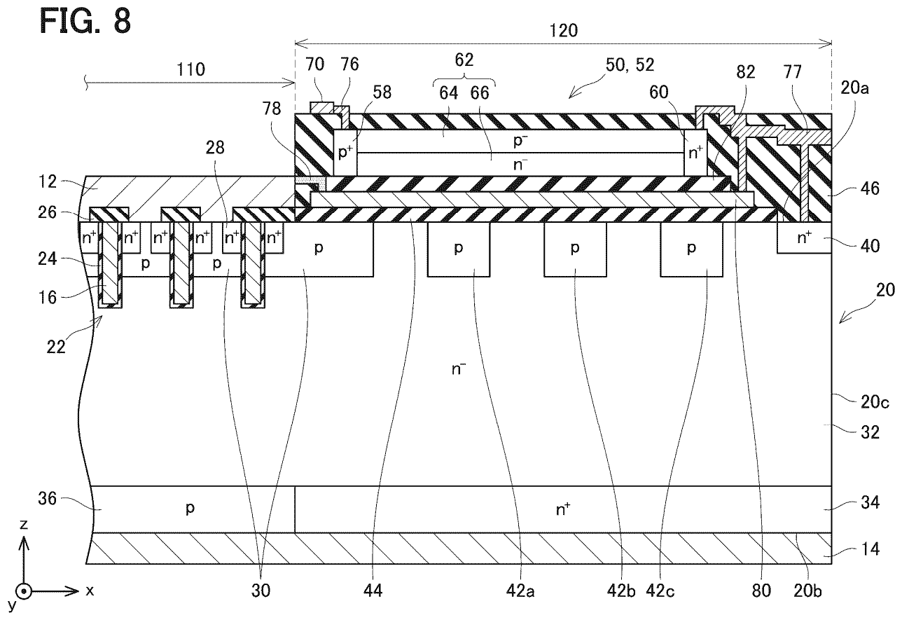

In the first to third embodiments, the MOSFET 10 is provided in the element region 110. However, an IGBT (Insulated Gate Bipolar Transistor) may be provided in the element region 110. At this time, as shown in FIG. 8, the semiconductor substrate 20 has a p-type collector layer 36 in place of the drain layer 34 in the element region 110. The collector layer 36 is in contact with the lower surface of the drift layer 32. The collector layer 36 is disposed in an area including the lower surface 20b of the semiconductor substrate 20 within the element region 110. Furthermore, when an IGBT is provided in the element region 110, the drain electrode 14 functions as a collector electrode, and the source electrode 12 functions as an emitter electrode.

In the first embodiment, it may be sufficient that the semiconductor device 100 has at least one set of the guard ring 42 and the semiconductor layer 50 disposed on the guard ring 42.

In the second and third embodiments, the semiconductor substrate 20 has plural guard rings 42. However, it may be sufficient that the semiconductor substrate 20 has at least one guard ring 42. In the second and third embodiments, the semiconductor substrate 20 may not have the guard ring 42.

In the first to third embodiments, the guard ring 42 has a ring shape surrounding the element region 110. However, the guard ring 42 may not have a ring shape surrounding the element region 110.

The structure of the diode 52 in the third embodiment is the same as that in the second embodiment. However, the structure of the diode 52 in the third embodiment may be the same as that in the first embodiment.

In the first to third embodiments, the semiconductor layer 50 is provided with the diode 52 having a p-type anode layer and an n-type cathode layer. However, the semiconductor layer 50 may be provided with a Schottky diode or the like.

In the first to third embodiments, the source electrode 12 is an example of upper electrode. The drain electrode 14 is an example of lower electrode. The peripheral n-type layer 40 is an example of a first n-type layer. The drain layer 34 is an example of a second n-type layer. The guard ring 42 is an example of a p-type voltage-resistant layer.

Although the embodiments have been described in detail above, these are merely examples and do not limit the scope of present disclosure. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising:
a semiconductor substrate having an element region and a peripheral region disposed around the element region;
an upper electrode covering an upper surface of the semiconductor substrate in the element region;
an insulating film covering an upper surface of the semiconductor substrate in the peripheral region;
a lower electrode covering a lower surface of the semiconductor substrate in an area over the element region and the peripheral region;
a semiconductor layer disposed on the insulating film and having a diode provided thereon;
an anode electrode provided on the semiconductor substrate; and
a switching element disposed in the element region to pass a current between the upper electrode and the lower electrode, wherein
the semiconductor substrate includes:
a first n-type layer disposed within the peripheral region and located in a range including a corner between the upper surface and a side surface of the semiconductor substrate;
a second n-type layer disposed within the peripheral region and located below the first n-type layer to be in contact with the lower electrode; and
an n-type drift layer distributed across the element region and the peripheral region to have an n-type impurity concentration lower than those of the first n-type layer and the second n-type layer,
the n-type drift layer is disposed between the first n-type layer and the second n-type layer and in contact with both of the first n-type layer and the second n-type layer,
an anode of the diode is electrically connected to the anode electrode, and
a cathode of the diode is electrically connected to the first n-type layer.

2. The semiconductor device according to claim 1, further comprising a semi-insulating film disposed between the insulating film and the semiconductor layer, wherein
the semi-insulating film is electrically connected to the upper electrode and the first n-type layer.

3. The semiconductor device according to claim 1, wherein
the diode has:
a first anode layer of p-type;
a first cathode layer of n-type spaced from the first anode layer in a lateral direction; and
a stacked portion disposed between the first anode layer and the first cathode layer,
the stacked portion has a structure in which a p-type second anode layer and an n-type second cathode layer are stacked with each other in an up-down direction,
the second anode layer has a lower p-type impurity concentration than the first anode layer,
the second cathode layer has a lower n-type impurity concentration than the first cathode layer,
the second anode layer is in contact with the first anode layer at a side surface of the stacked portion, and
the second cathode layer is in contact with the first cathode layer at a side surface of the stacked portion.

4. The semiconductor device according to claim 1, further comprising a p-type voltage-resistant layer disposed within the peripheral region and located between the element region and the first n-type layer in a range including the upper surface of the semiconductor substrate, wherein
the p-type voltage-resistant layer is spaced apart from the element region and from the first n-type layer, and
the drift layer is present between the p-type voltage-resistant layer and the element region, and between the p-type voltage-resistant layer and the first n-type layer.

5. The semiconductor device according to claim 4, wherein the semiconductor layer is provided within a range overlapping the p-type voltage-resistant layer in a thickness direction of the semiconductor substrate.

6. The semiconductor device according to claim 5, wherein
the p-type voltage-resistant layer is one of a plurality of p-type voltage-resistant layers,
the semiconductor layer includes a first semiconductor layer disposed over a first p-type voltage-resistant layer of the plurality of p-type voltage-resistant layers, and a second semiconductor layer disposed over a second p-type voltage-resistant layer of the plurality of p-type voltage-resistant layers, and
a first diode provided in the first semiconductor layer and a second diode provided in the second semiconductor layer are connected in series between the anode electrode and the first n-type layer with an anode facing the anode electrode.

7. The semiconductor device according to claim 5, wherein
the p-type voltage-resistant layer has a ring shape surrounding the element region,
the diode has a p-type anode layer provided in the semiconductor layer and an n-type cathode layer provided in the semiconductor layer, and
the anode layer and the cathode layer are arranged along a longitudinal direction of the p-type voltage-resistant layer.

8. The semiconductor device according to claim 5, wherein
the p-type voltage-resistant layer has a ring shape surrounding the element region,
the diode has a p-type anode layer provided in the semiconductor layer and an n-type cathode layer provided in the semiconductor layer, and
a pn junction at a boundary between the anode layer and the cathode layer has a ring shape extending along the p-type voltage-resistant layer.
